(19) United States
(12) Patent Application Publication
(10) Pub. No.: US 2026/0336102 A1
(43) Pub. Date: Oct. 29, 2026

(54) MOUNTING ASSISTANCE DEVICE AND MOUNTING ASSISTANCE METHOD

(71) Applicant: FUJI CORPORATION, Chiryu (JP)

(72) Inventor: Kohei SUGIHARA, Nishio-shi (JP)

(73) Assignee: FUJI CORPORATION, Chiryu (JP)

(21) Appl. No.: 19/481,945

(22) PCT Filed: Jun. 16, 2023
(86) PCT No.: PCT/JP2023/022506

§ 371 Date: Nov. 6, 2025

(51) Int. Cl. B25J 9/16; G06Q 10/047; G06T 7/00; G06T 7/70; G06V 20/60; H05K 13/08

(52) U.S. Cl. CPC B25J 9/163; B25J 9/1664; G06Q 10/047; G06T 7/0004; G06T 7/70; H05K 13/086; G06T 2207/30141; G06V 20/60; G06V 2201/06

(57) ABSTRACT

A mounting assistance device is applied to a component mounter configured to execute a pickup cycle in which a mounting head is moved to sequentially pick up components accommodated in the multiple cavities and a mounting cycle in which multiple components are sequentially mounted on a board, and includes a path search section configured to search for path patterns that are candidates for a movement path of the mounting head in the pickup cycle based on accommodation information indicating, among the multiple cavities, positions of the multiple cavities that accommodate the components such that the components are available for pickup, and a path setting section configured to set as the movement path the path pattern selected based on a movement distance of the mounting head calculated for each of multiple path patterns.

### TECHNICAL FIELD

The present disclosure relates to a mounting assistance device and a mounting assistance method.

### BACKGROUND ART

A mounting assistance device assists a mounting process by a component mounter using a bulk feeder. The bulk feeder is installed in the component mounter that mounts components on a board, and supplies components in a bulk state (see Patent Literature 1). In the mounting process, the component mounter executes a pickup cycle of moving a mounting head and sequentially picking up the components accommodated in multiple cavities, and a mounting cycle of sequentially mounting the multiple components on the board.

### CITATION LIST

### Patent Literature

Patent Literature 1: JP2011-114084

### BRIEF SUMMARY

### Technical Problem

Here, in the mounting process, the component mounter executes image processing of recognizing a supply state of the component by the bulk feeder, and controls an operation of picking up the component using a suction nozzle based on a result of the image processing. In the component mounter, it is desired to shorten a time required for the mounting process.

An object of the present description is to provide a mounting assistance device and a mounting assistance method that assist a mounting process by improving the efficiency of a pickup cycle in accordance with a supply state of a component by a bulk feeder.

### Solution to Problem

The present description discloses a mounting assistance device applied to a component mounter configured to execute a pickup cycle in which a mounting head is moved to sequentially pick up components accommodated in multiple cavities and a mounting cycle in which the multiple components are sequentially mounted on a board, the mounting assistance device including: a path search section configured to search for path patterns that are candidates for a movement path of the mounting head in the pickup cycle based on accommodation information indicating, among the multiple cavities, positions of the multiple cavities that accommodate the components such that the components are available for pickup; and a path setting section configured to set as the movement path the path pattern selected based on a movement distance of the mounting head calculated for each of multiple of the path patterns.

The present description discloses a mounting assistance method applied to a component mounter configured to execute a pickup cycle in which a mounting head is moved to sequentially pick up components accommodated in multiple cavities and a mounting cycle in which the multiple components are sequentially mounted on a board, the mounting assistance method including: a path search step of searching for path patterns that are candidates for a movement path of the mounting head in the pickup cycle based on accommodation information indicating, among the multiple cavities, positions of the multiple cavities that accommodate the components such that the components are available for pickup; and a path setting step of setting as the movement path the path pattern selected based on a movement distance of the mounting head calculated for each of multiple of the path patterns.

### Advantageous Effects

With such a configuration, since the movement distance of the mounting head during the pickup cycle can be shortened, the efficiency of the pickup cycle and the mounting process can be improved.

### BRIEF DESCRIPTION OF DRAWINGS

FIG. 1 is a plan view schematically illustrating a component mounter.

FIG. 2 is a side view schematically illustrating a part of a bulk feeder including a supply region.

FIG. 3 is a plan view as seen from direction III of FIG. 2.

FIG. 4 is a block diagram illustrating the component mounter to which a mounting assistance device is applied.

FIG. 5 is a flowchart illustrating a mounting process by the component mounter.

FIG. 6 is a flowchart illustrating a process of recognizing a supply state.

FIG. 7A is a view illustrating image data obtained by imaging the supply region.

FIG. 7B is a diagram illustrating a result of the process of recognizing the supply state.

FIG. 8 is a flowchart illustrating a process of setting a movement path.

FIG. 9A is a diagram illustrating a movement path before change and an initial solution.

FIG. 9B is a diagram illustrating the movement path set based on a path pattern.

FIG. 10 is a graph illustrating a movement distance of each of the movement path that is the initial solution, the set movement path, and a movement path set with a condition.

FIG. 11 is a diagram illustrating groups obtained by dividing the result of the process of recognizing the supply state.

### DESCRIPTION OF EMBODIMENTS

### 1. Overview of Mounting Assistance Device 50

Mounting assistance device 50 assists a mounting process by component mounter 10 using bulk feeder 30. In the present embodiment, mounting assistance device 50 is incorporated in control device 20 of component mounter 10. Mounting assistance device 50 improves the efficiency of a pickup cycle in accordance with a supply state of a component supplied by bulk feeder 30.

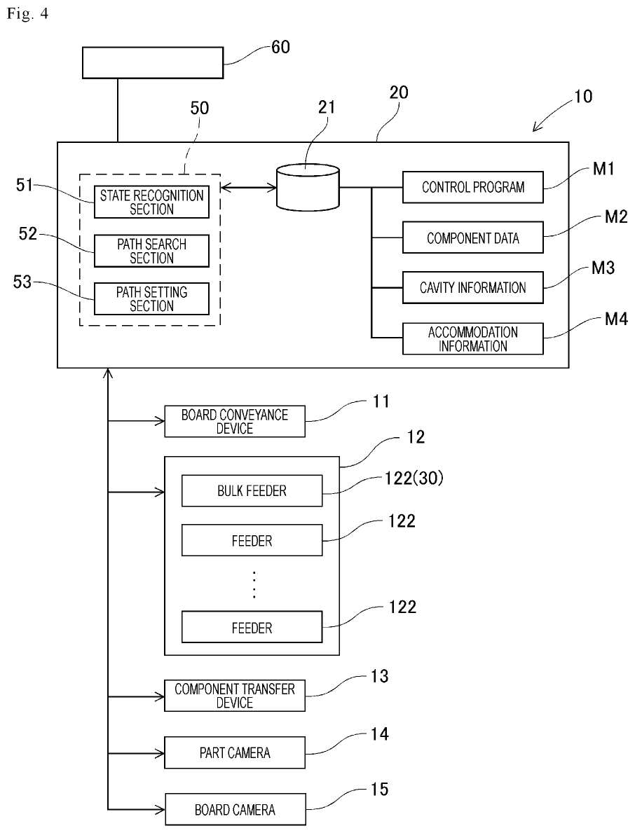

Component mounter 10 executes a mounting process of mounting the components on board 91 as predetermined board work. Component mounter 10 is installed in a conveyance direction of board 91 together with other board work machines to form a production line. Each of the multiple board work machines is communicably connected to host computer 60 (see FIG. 4) that centrally controls the production line. The production line includes a printer, component mounter 10, a reflow oven, and an inspection machine as the multiple board work machines.

### 2. Configuration of Component Mounter 10

### 2-1. Board Conveyance Device 11

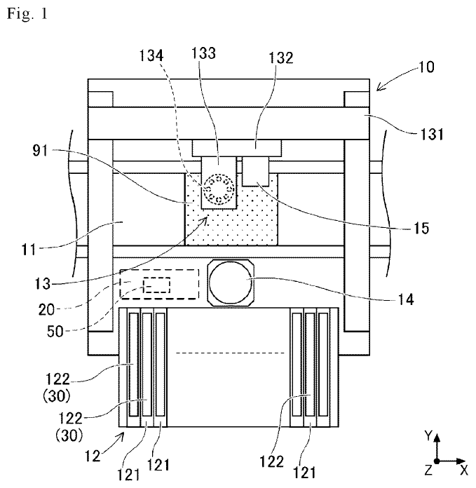

As illustrated in FIG. 1, component mounter 10 includes board conveyance device 11. Board conveyance device 11 subsequently conveys board 91 in the conveyance direction and positions board 91 at a predetermined position in component mounter 10.

### 2-2. Component Supply Device 12

Component mounter 10 includes component supply device 12. Component supply device 12 supplies the components to be mounted on board 91. In component supply device 12, feeder 122 is set in each of multiple slots 121. A tape feeder that supplies the components such that the components are available for pickup, for example, by feeding and moving a carrier tape accommodating a large number of components is applied as feeder 122. In addition, bulk feeder 30 that supplies the components accommodated in a bulk state such that the components are available for pickup is applied as feeder 122. Details of bulk feeder 30 will be described later.

### 2-3. Component Transfer Device 13

Component mounter 10 includes component transfer device 13. Component transfer device 13 transfers the component supplied by component supply device 12 to a predetermined mounting position on board 91. Component transfer device 13 includes head drive device 131, moving section 132, mounting head 133, and suction nozzle 134. Head drive device 131 moves moving section 132 in a horizontal direction (X direction and Y direction) by a linear movement mechanism. Mounting head 133 is detachably fixed to moving section 132 by a clamp member (not illustrated) and is movable in the horizontal direction in component mounter 10.

Mounting head 133 supports multiple suction nozzles 134 such that the multiple suction nozzles 134 can be rotated and can be lifted and lowered. Suction nozzle 134 is a holding member that picks up and holds the component supplied by feeder 122. Suction nozzle 134 picks up the component supplied by feeder 122 by using negative pressure air. A chuck or the like that holds the component by gripping the component can be adopted as the holding member attached to mounting head 133.

### 2-4. Part Camera 14 and Board Camera 15

Component mounter 10 includes part camera 14 and board camera 15. Part camera 14 and board camera 15 are digital imaging devices including imaging elements such as CMOS. Part camera 14 and board camera 15 perform imaging based on a control signal, and send image data acquired by the imaging. Part camera 14 is configured to image the component held by suction nozzle 134 from below. Board camera 15 is provided on moving section 132 movably in the horizontal direction and integrally with mounting head 133. Board camera 15 is configured to image board 91 from above.

Further, board camera 15, in addition to having a surface of board 91 as an imaging target, can have various devices or the like as imaging targets as long as the various devices are within a movement range of moving section 132. For example, in the present embodiment, as illustrated in FIG. 3, board camera 15 can image supply region As to which bulk feeder 30 supplies the components or fiducial mark 49 provided on an upper part of bulk feeder 30 within a field of view of the camera. As described above, board camera 15 can be used commonly to image different imaging targets to acquire image data used for various types of image processing.

### 2-5. Control Device 20

Component mounter 10 includes control device 20. Control device 20 is mainly configured with a CPU, various memories, and a control circuit. Control device 20 includes storage section 21 as illustrated in FIG. 4. Storage section 21 is configured with a hard disk device or a storage device such as a flash memory. Storage section 21 of control device 20 stores various data such as control program M1, component data M2, cavity information M3, and accommodation information M4 that are used for controlling the mounting process.

Control program M1 indicates, in a scheduled mounting order, a mounting position, a mounting angle, and a component type of the components to be mounted on board 91 in the mounting process. Here, the mounting process includes a process of repeating a pick-and-place cycle (PP cycle) including the pickup cycle and the mounting cycle multiple times. The above-described “pickup cycle” is a process of repeating a pickup operation of picking up, using suction nozzle 134, the components supplied by component supply device 12, multiple times.

Here, the component that is a pickup target may be supplied by bulk feeder 30 in the pickup cycle. When cavities 45 (see FIG. 3) for individually accommodating the components are formed in supply region As of bulk feeder 30, the pickup cycle is an operation of sequentially picking up the components accommodated in multiple cavities 45 by moving mounting head 133.

The “mounting cycle” is a process of sequentially mounting the picked-up components on board 91, and specifically, a process of repeating a mounting operation of mounting the component at a predetermined mounting position on board 91 at a predetermined mounting angle multiple times. As described above, an execution order of the PP cycle including multiple pickup operations and mounting operations grouped in consideration of the number of suction nozzles 134 supported by mounting head 133, the movement distance of mounting head 133, and the like is set in advance in control program M1.

Component data M2 includes shape data of each type of the component. The “shape data” includes at least one of an outer edge shape of the component, a shape of a characteristic portion of the component, and a dimension of the component. The “outer edge shape” of the component corresponds to a shape of an outer edge when the inside and the background of the component are divided using the outer edge of the component as a boundary.

The “shape of the characteristic portion” of the component corresponds to a boundary shape of the characteristic portion in appearance resulting from a shape, a pattern, a color, and the like of the component. A corner, a bump, a terminal, a lead portion, and the like of the component can be applied as the characteristic portion of the component. In addition, component data M2 may include, for example, a maximum allowable movement speed (acceleration), a collection position (for example, a position in contact with suction nozzle 134), and the like for each component, in addition to the shape data.

Cavity information M3 is information in which information on cavity 45 formed in supply region As of bulk feeder 30 is associated with identification information (ID) of bulk feeder 30. Cavity information M3 may include a shape (including a length and a depth of each side), a position, an orientation, the type of corresponding component, and the like of cavity 45 in supply region As. Accommodation information M4 is information indicating, among multiple cavities 45, the positions of multiple cavities 45 that accommodate the components such that the components are available for pickup. Details of accommodation information M4 will be described later.

Control device 20 executes the process of recognizing the holding state of the component held by each of multiple holding members (suction nozzles 134). Specifically, control device 20 performs image processing on the image data acquired by capturing an image with part camera 14 and recognizes a position and an angle of each component relative to a reference position of mounting head 133. In addition to part camera 14, for example, control device 20 may perform image processing on the image data acquired by imaging the component from a side, below, or above by using a head camera unit or the like integrally provided on mounting head 133.

In the mounting process, control device 20 controls the mounting operation by mounting head 133 such that the component is mounted on board 91 in a predetermined posture. In this case, control device 20 controls the mounting operation based on a holding state of the recognized component. That is, control device 20 corrects a position of mounting head 133 and an angle of suction nozzle 134 around a Q-axis (rotation axis of suction nozzle 134) to correct deviations of a position and an angle of the component held by suction nozzle 134 relative to the Q-axis. As a result, the component held by suction nozzle 134 is mounted at a predetermined mounting position and a predetermined mounting angle that are indicated by control program M1.

### 3. Configuration of Bulk Feeder 30

Bulk feeder 30 is set in component mounter 10 to function as a part of component supply device 12. Bulk feeder 30 supplies the components accommodated in a component case in a bulk state (dispersed state in which each posture is irregular) that is not packaged like a carrier tape. Accordingly, unlike the tape feeder, bulk feeder 30 does not use the carrier tape, which has the advantage that loading of the carrier tape and collection of used tape can be omitted.

For example, there is bulk feeder 30 of a type that supplies the component in an irregular posture to supply region As having a plane shape. However, when components are so close to be in contact with each other or accumulated (in a state of being overlapped in an up-down direction) or the components are placed horizontally with width directions aligned in the up-down direction in supply region As, component mounter 10 cannot regard the components as pickup targets. Therefore, in order to increase a ratio of components that are available for pickup, there is bulk feeder 30 of a type that supplies components to supply region As in an aligned state. In the present embodiment, bulk feeder 30 of the type in which components are aligned will be described as an example.

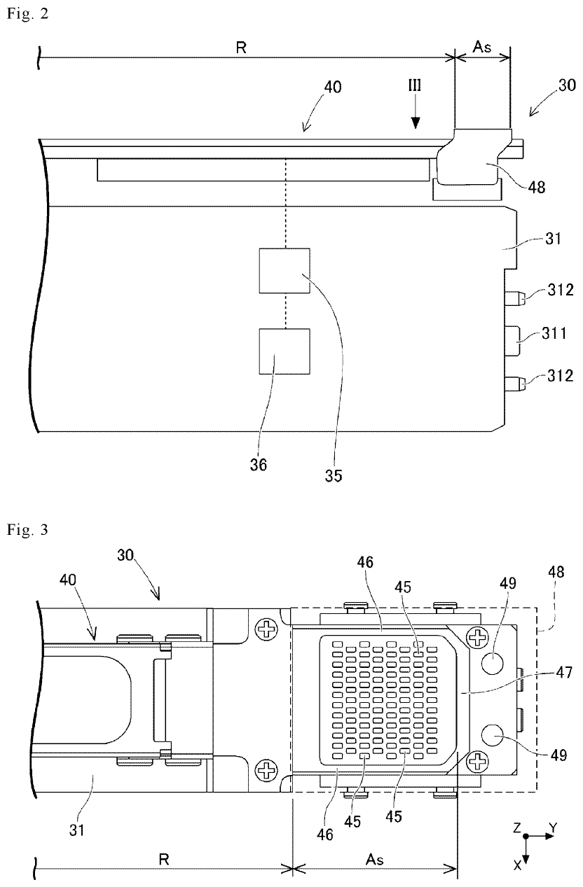

In bulk feeder 30, track unit 40 is vibratably and detachably attached to feeder main body 31 formed in a flat box shape. Connector 311 and two positioning pins 312 are provided on a front portion (right side end portion in FIG. 2) of feeder main body 31. When feeder main body 31 is set in slot 121 of component supply device 12, power is supplied via connector 311, and feeder main body 31 can communicate with control device 20 of component mounter 10.

Track unit 40 is vibrated by vibration application device 35. Track unit 40 is formed with conveyance path R through which multiple components are conveyed, and supply region As that communicates with conveyance path R and is open upward such that the multiple components are available for pickup. Track unit 40 is formed to extend in a front-rear direction (left-right direction in FIG. 3) of feeder main body 31. Pair of side walls 46 protruding upward is formed along both edges of track unit 40 in a width direction (up-down direction in FIG. 3). Pair of side walls 46 are wall members that surround a peripheral edge of conveyance path R together with front end portion 47 of track unit 40 and prevent the components conveyed along conveyance path R from falling out.

As illustrated in FIG. 3, multiple cavities 45 are formed in supply region As of track unit 40. Each of multiple cavities 45 is open upward to accommodate the components in a posture in which a thickness direction of the component is in the up-down direction. In the present embodiment, multiple cavities 45 are arranged in a staggered shape. Here, the “supply region As” of track unit 40 is a region to which the components are supplied in a bulk state, and is a region from which the components are available for pickup by suction nozzle 134 supported by mounting head 133. In addition, the “conveyance path R” of track unit 40 is a component passage through which the components being distributed from the component case side to track unit 40 are conveyed to supply region As.

In addition, vibration application device 35 vibrates track unit 40 so that multiple components are conveyed along conveyance path R. When track unit 40 vibrates, forward and upward external force or rearward and upward external force is applied to the components. As a result, multiple components are conveyed either to the front side or to the rear side of track unit 40. Bulk feeder 30 conveys the components when the operation of vibration application device 35 is controlled by feeder control device 36, and performs the operation of supplying the components to supply region As. When the components are accommodated in multiple cavities 45 by the supply operation, suction nozzle 134 is in a state of being able to pick up the components.

Shutter 48 that can close the opening of supply region As is provided above track unit 40. When track unit 40 is attached to feeder main body 31, the opening and closing operations of shutter 48 are controlled by a shutter drive device (not illustrated). By opening and closing shutter 48, bulk feeder 30 can prevent the components from exiting and foreign matter from entering supply region As

### 4. Mounting Process by Component Mounter 10

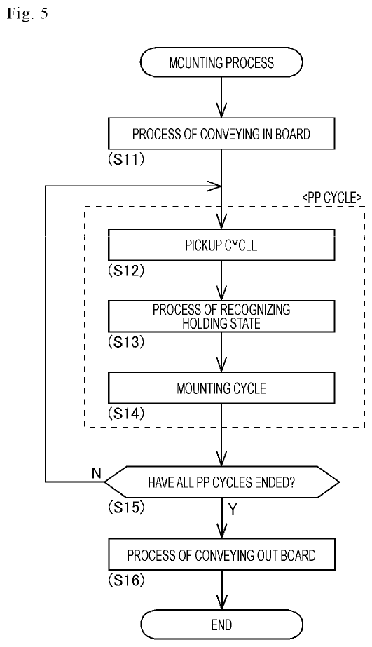

The mounting process by component mounter 10 will be described with reference to FIG. 5. Here, it is assumed that bulk feeder 30 is set in component supply device 12. In the mounting process, first, as illustrated in FIG. 5, board conveyance device 11 of component mounter 10 executes a process of conveying in board 91 (S11). Accordingly, board 91 is conveyed into component mounter 10 and positioned at a predetermined position in component mounter 10.

In parallel with the mounting process, the operation of supplying the component by bulk feeder 30 is executed at a predetermined timing. After the execution of the operation of supplying the component, the process of recognizing the supply state of the component in supply region As is executed. The process of recognizing the supply state will be described in detail later.

Next, control device 20 executes the PP cycle. In the PP cycle, control device 20 executes the pickup cycle in which the pickup operation of picking up the component using multiple suction nozzles 134 is repeated (S12). In this case, control device 20 controls the operation of mounting head 133 in the pickup operation so that mounting head 133 is sequentially positioned in accordance with the positions of components that are available for pickup.

In addition, when bulk feeder 30 supplies the component that is the pickup target, control device 20 switches, as appropriate, a coordinate value that is the center of cavity 45 and a coordinate value of a reference position of the component as the position of the component available for pickup, and positions suction nozzle 134. The movement path of mounting head 133 in the pickup cycle ($12) is set by mounting assistance device 50. Details of the process of setting the movement path will be described later.

Subsequently, control device 20 executes a process of recognizing the holding state of the component held by each of multiple suction nozzles 134 (S13). Specifically, control device 20 moves mounting head 133 to a position above part camera 14, and sends an imaging command to part camera 14. Control device 20 recognizes the posture (position and angle) of the component held by each of multiple suction nozzles 134 by performing image processing on the image data acquired by capturing an image with part camera 14.

Then, control device 20 executes the mounting cycle in which the mounting operation of mounting the components is repeated using multiple suction nozzles 134 (S14). In the mounting operation of the mounting cycle (S14), control device 20 controls the operation of mounting head 133 so that each of the components is mounted at the mounting position designated by the control program. Further, control device 20 controls the operation of mounting head 133 so that suction nozzle 134 is positioned and oriented relative to the mounting position based on the result of the recognition process (S13).

Control device 20 determines whether all the PP cycles have ended based on the control program (S15). When all the PP cycles have not ended (S15: No), the PP cycle (S12 to S14) is executed. When all the PP cycles have been completed (S15: Yes), control device 20 executes a process of conveying out board 91 (S16). In the process of conveying out board 91, board conveyance device 11 unclamps positioned board 91 and conveys board 91 out of component mounter 10.

### 5. Configuration of Mounting Assistance Device 50

A configuration of mounting assistance device 50 will be described with reference to FIGS. 4 and 6 to 11. Mounting assistance device 50 assists the pickup cycle executed by control device 20 of component mounter 10 in the mounting process. In the pickup cycle including the component supplied by bulk feeder 30 as the pickup target, the image processing of recognizing the supply state of the component by bulk feeder 30 is first executed, and the operation of picking up the component using suction nozzle 134 is controlled based on the result of the image processing.

Here, when the process of supplying the components to supply region As of bulk feeder 30 is performed, the components are not necessarily accommodated in all cavities 45 such that the components are available for pickup. Therefore, in the process of recognizing the supply state, cavities 45 accommodating the components such that the components are available for pickup are recognized, and the movement path of mounting head 133 is set such that suction nozzles 134 are sequentially positioned with respect to cavities 45.

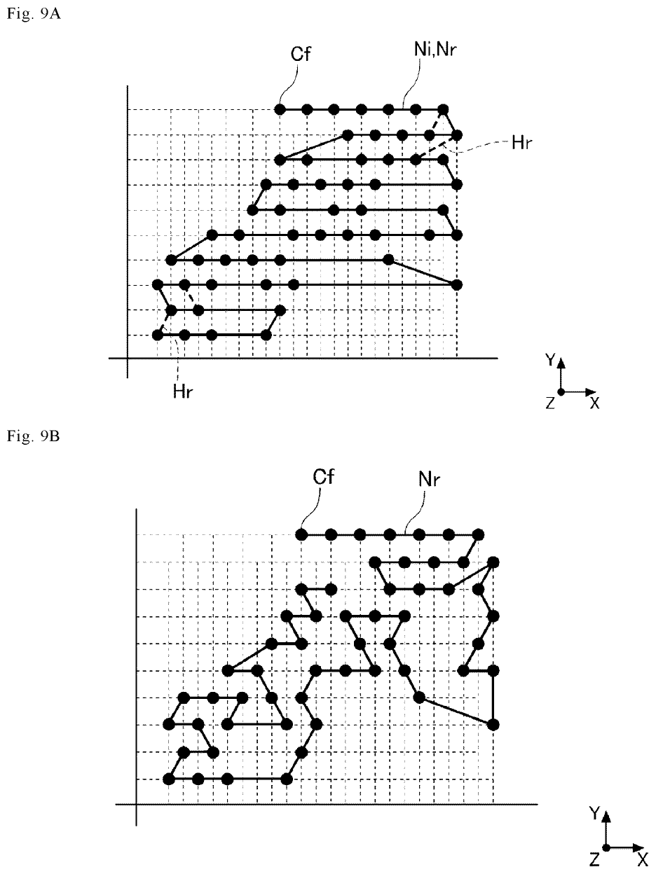

Multiple cavities 45 in the present embodiment are arranged such that cavity rows including multiple cavities 45 arranged along a first direction (X direction in the present embodiment) are arranged in a second direction (Y direction in the present embodiment) intersecting the X direction. Therefore, as the movement path, first, cavity 45 that first accommodates the component such that the component is available for pickup, from cavity 45 located at a first end in the X direction of the cavity row close to board 91 among multiple cavities 45 toward a second end in the X direction is set as a start position of the pickup operation. Then, a meandering movement path can be set such that mounting head 133 moves from cavity 45 at the start position to the second end in the X direction, then moves to the cavity row adjacent in the Y direction, and then moves toward the first end in the X direction (see FIG. 9A).

It can be said that the movement path as described above is efficient in a case where multiple cavities 45 accommodating the components such that the components are available for pickup are dispersed evenly. However, in practice, multiple cavities 45 that accommodate components such that the components are available for pickup in supply region As may be biased, and there may be a movement path more efficient than the movement path obtained by the above-described setting method. Therefore, mounting assistance device 50 adopts a configuration for assisting the mounting process by improving the efficiency of the pickup cycle in accordance with the supply state of the component by bulk feeder 30.

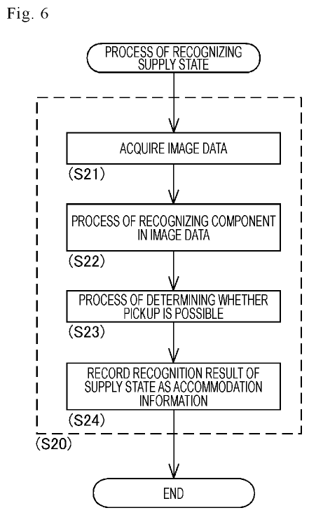

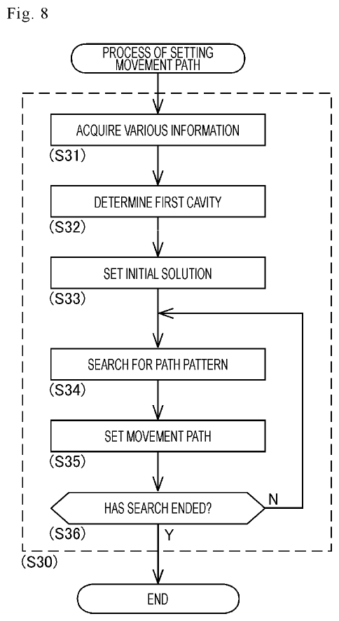

In the present embodiment, as illustrated in FIG. 4, mounting assistance device 50 includes state recognition section 51, path search section 52, and path setting section 53. State recognition section 51 executes a process of recognizing the supply state (S20) illustrated in FIG. 6. Path search section 52 and path setting section 53 execute a process of setting the movement path (S30) illustrated in FIG. 8. Control device 20 controls the operation of mounting head 133 in the pickup cycle in accordance with the movement path set by the setting process.

### 5-1. State Recognition Section 51

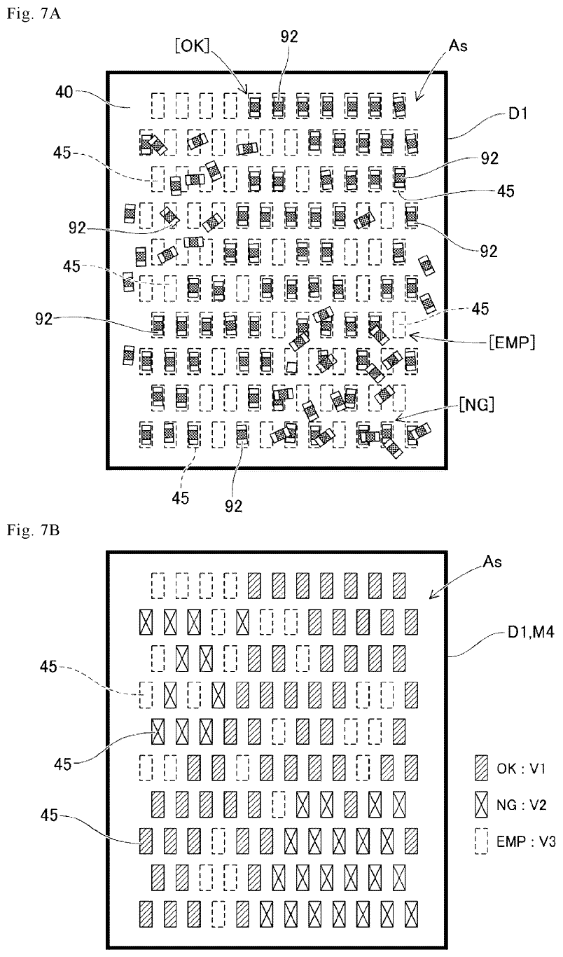

State recognition section 51 performs image processing on image data D1 (see FIG. 7A) acquired by imaging supply region As for components 92 in the bulk feeder in which multiple cavities 45 are formed, recognizes the supply state of components 92 in supply region As, and generates accommodation information M4. The supply state of components 92 includes a determination result of whether component 92 supplied to supply region As of bulk feeder 30 is suitable for the target of the pickup operation by component mounter 10.

More specifically, as illustrated in FIG. 6, state recognition section 51 acquires image data D1 by capturing an image with the camera (in the present embodiment, board camera 15) (S21). In supply region As, there may be a large number of components 92 in a bulk state, such as components 92 accommodated in a normal posture in cavities 45, components 92 outside cavities 45, components 92 that are in contact with each other or deposited on each other, and components 92 standing on their side.

Next, state recognition section 51 performs image processing on image data D1 and executes a process of recognizing component 92 in image data D1 (S22). More specifically, state recognition section 51 recognizes component 92 included in image data D1 by, for example, blob analysis. State recognition section 51 binarizes image data D1 using a predetermined threshold to generate a blob. State recognition section 51 recognizes component 92 based on the size and the shape of the generated blob and component data M2.

Subsequently, state recognition section 51 executes a process of determining whether recognized component 92 can be picked up (S23). In other words, this determination process is a process of determining whether recognized component 92 is suitable for the target of the pickup operation by component mounter 10. That is, when component 92 present in supply region As is not accommodated in cavity 45 or is in contact with another component 92, it is determined that component 92 cannot be picked up (is not suitable for the pickup operation).

State recognition section 51 records the recognition result of the supply state as accommodation information M4 (S24). In the present embodiment, state recognition section 51 determines the state of each of multiple cavities 45. Accordingly, multiple cavities 45 are classified into an accommodation cavity (“OK” indicated by hatching in FIG. 7B) that accommodates component 92 such that component 92 is available for pickup, an NG cavity (“NG” indicated by adding an X mark connecting diagonal lines in FIG. 7B) which component 92 is present around but cannot be picked up, and an empty cavity (“EMP” indicated by a dashed line in FIG. 7B) around which component 92 is not present. State recognition section 51 calculates the number (V1, V2, and V3) of the states (OK, NG, and EMP) of multiple cavities 45.

Accommodation information M4 indicates, among multiple cavities 45, the positions of multiple cavities 45 that accommodate the components such that the components are available for pickup. When there is a component suitable for the pickup operation in the process of recognizing the supply state, state recognition section 51 recognizes the position and angle of the component. As described above, in addition to the states (OK, NG, and EMP) of each cavity 45, the position (for example, the center coordinates of the component) and the angle (for example, the inclination angle relative to the reference angle of cavity 45) of the component available for pickup in cavity 45 are recorded in accommodation information M4.

The process of recognizing the supply state (S20) is executed after the operation of supplying component 92 by bulk feeder 30 is executed. State recognition section 51 can generate accommodation information M4 by executing the recognition process, for example, in parallel with the process of conveying in the board (S11) or the PP cycle. When component 92 is picked up from bulk feeder 30, accommodation information M4 is updated in accordance with the pickup operation, and is discarded when the operation of supplying component 92 by bulk feeder 30 is executed.

### 5-2. Path Search Section 52

Path search section 52 searches for path patterns that are candidates for the movement path of mounting head 133 in the pickup cycle based on accommodation information M4. Here, the “movement path” is a path when mounting head 133 performs the XY movement to pick up components 92 from multiple cavities 45 in the pickup cycle of the PP cycle, and indicates the positions and the orders of multiple cavities 45 in which mounting head 133 is positioned.

As illustrated in FIGS. 9A and 9B, mounting head 133 moves to predetermined cavity 45 along movement path Nr. Specifically, when executing the pickup operation, control device 20 adjusts the position of mounting head 133 and the angle of suction nozzle 134 in consideration of the position and the angle of component 92 accommodated in cavity 45.

The “path pattern” is a candidate for movement path Nr searched for until final movement path Nr is set, and is searched for, for example, by switching the start point or the end point between a route having two cavities 45 as the start point and the end point in a predetermined path pattern and another route.

Path search section 52 searches for the path patterns based on a predetermined condition from the viewpoint of improving the efficiency of the pickup cycle.

### 5-3. Path Setting Section 53

Path setting section 53 sets, as movement path Nr, the path pattern selected based on movement distance Lm of mounting head 133 calculated for each of the multiple path patterns. Specifically, path setting section 53 calculates the sum of the lengths of the routes included in the path patterns as movement distance Lm of mounting head 133.

Movement distance Lm substantially coincides with the movement distance of mounting head 133 that moves along movement path Nr set in the path pattern, and correlates with a time required for the pickup cycle. That is, the evaluation using movement distance Lm for each path pattern by path setting section 53 is equivalent to the evaluation using the time required for the pickup cycle calculated for each path pattern.

### 6. Assistance of Mounting Process by Mounting Assistance Device 50 (Mounting Assistance Method)

### 6-1. Process of Setting Movement Path

The process of setting the movement path by mounting assistance device 50 (S30) will be described. Here, the process of setting the movement path (S30) is executed after the operation of supplying component 92 by bulk feeder 30 is executed and the process of recognizing the supply state (S20) is completed. For example, when the supply operation by bulk feeder 30 is executed after the pickup cycle of the first PP cycle is completed, supply region As of bulk feeder 30 is imaged and image data D1 is acquired after the mounting cycle of the first PP cycle has ended.

The process of recognizing the supply state (S20) is executed using image data D1, and then the process of setting the movement path (S30) is executed. In this case, mounting head 133 can execute the above-described processes (S20 and S30) in parallel with the pickup operation of component 92 supplied by feeder 122 that does not require the result of the process of setting the movement path (S30) in the pickup cycle of the second PP cycle.

In the process of setting the movement path (S30), first, path search section 52 acquires various information (S31). The various information may include control program M1, component data M2, cavity information M3, and conditions and parameters used for setting the movement path, in addition to accommodation information M4 indicating, among multiple cavities 45, the positions of multiple cavities 45 that accommodate components 92 such that components 92 are available for pickup.

Next, path search section 52 determines the first cavity (S32, determination step). Here, the “first cavity” is cavity 45 in which component 92 is first picked up by mounting head 133 in path pattern Hr among multiple cavities 45 accommodating components 92 such that components 92 are available for pickup. That is, the “first cavity” is a position that becomes a start point of all path patterns Hr. Path search section 52 may set first cavity Cf based on the position of mounting head 133 when the pickup cycle is started.

Specifically, in the cavity row that includes at least one accommodation cavity among the multiple cavity rows and is close to board 91, the accommodation cavity closest to the current position of mounting head 133 is determined as first cavity Cf. When first cavity Cf is determined by path search section 52, mounting head 133 can start moving toward first cavity Cf. As a result, mounting head 133 can be moved without waiting for the end of the process of setting the movement path (S30), and the occurrence of waiting time can be prevented.

Here, in the present embodiment, path search section 52 and path setting section 53 search for path pattern Hr and set movement path Nr, using an algorithm applied to solve a traveling salesman problem. That is, path search section 52 and path setting section 53 evaluate the sum of the lengths of the routes as the movement distance of mounting head 133 in path pattern Hr, where multiple cavities 45 that accommodate components 92 such that components 92 are available for pickup are nodes, and a combination of the routes circulating multiple cavities 45 once each is one path pattern Hr.

As the algorithm applied to solve the traveling salesman problem, a neural network (NN) method and a 2-opt method are known. The algorithm to be applied can be freely set. For example, when an algorithm that makes it easy to experimentally obtain an optimal solution in accordance with the supply state of component 92 (the ratio of the accommodation cavities, the degree of bias of the accommodation cavities) is grasped in advance, the algorithm to be applied may be switched in accordance with the recognized supply state.

When searching for path pattern Hr using the algorithm as described above, path search section 52 uses first cavity Cf as a reference when first cavity Cf is determined. Then, path search section 52 sets an initial solution for the algorithm (S33). Specifically, path search section 52 provides preliminary path Ni formed by connecting end portions of paths (paths in the X direction) along the respective adjacent cavity rows with a path along the Y direction, to the algorithm as the initial solution. As illustrated in FIG. 9A, preliminary path Ni that is the initial solution corresponds to the movement path before the efficiency is improved by mounting assistance device 50.

Path search section 52 searches for path pattern Hr obtained by changing the route from the initial solution with first cavity Cf as a reference (fixed start point) (S34, path search step). In this case, when mounting head 133 starts moving toward first cavity Cf, path search section 52 executes a search step (S34) during a period in which mounting head 133 moves. Then, when path search section 52 generates path pattern Hr as the search result, path search section 52 executes the process of setting the movement path (S35, path setting step).

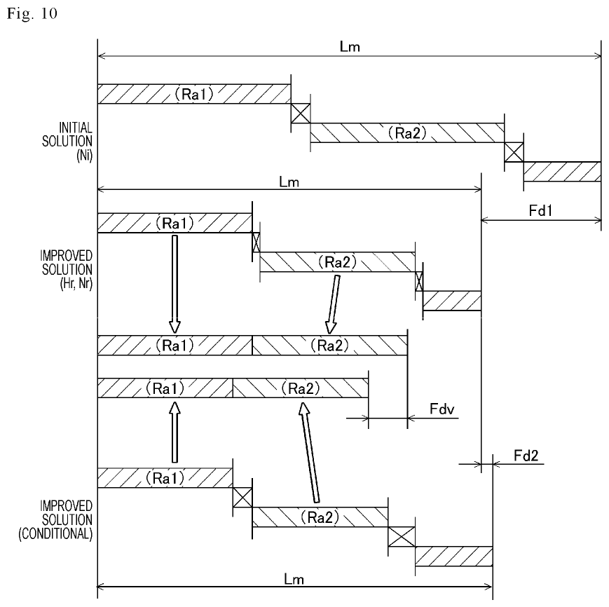

In the present embodiment, as illustrated in FIG. 10, path setting section 53 compares movement distance Lm (the sum of the lengths of the routes) of mounting head 133 in preliminary path Ni that is the initial solution with movement distance Lm of mounting head 133 in searched path pattern Hr, and temporarily sets path pattern Hr as movement path Nr when there is difference Fd1 and movement distance Lm is shorter. Path setting section 53 updates movement path Nr to be overwritten each time movement distance Lm of mounting head 133 in path pattern Hr generated next becomes shorter.

When the search for the path pattern has not ended (S36: No), the processes (S34 and S35) are repeated. When the search for the path pattern has ended (S36: Yes), finally set movement path Nr is applied to the movement of mounting head 133 in the pickup cycle. The end of the search for the path pattern includes a case where all the path patterns (excluding obviously redundant patterns) are searched for using the algorithm and a case where the search is terminated due to the degree of progress of the pickup cycle.

Specifically, first, by the above-described processes (S34 and S35), movement path Nr as illustrated in FIG. 9B is set by the above-described algorithm for movement path Nr (FIG. 9A) for which the initial solution is preliminary path Ni. Then, when the pickup cycle is executed in parallel with the process of setting the movement path (S30), mounting head 133 is moved along movement path Nr that is temporarily set. Then, in the execution period of the pickup cycle, the search for path pattern Hr by path search section 52 (S34) and the setting of movement path Nr by path setting section 53 (S35) are continued for a portion of movement path Nr not yet reached by mounting head 133.

As described above, control device 20 of component mounter 10 moves mounting head 133 along movement path Nr that is the best at the present time by mounting assistance device 50, and moves mounting head 133 along movement path Nr when more efficient movement path Nr is set in the portion not yet reached by mounting head 133 until the end of the pickup cycle. When the pickup cycle ends, the unreached portion of movement path Nr disappears, and the search for the path pattern ends.

With the configuration of mounting assistance device 50 as described above, since movement distance Lm of mounting head 133 in the pickup cycle can be shortened, the efficiency of the pickup cycle and the mounting process can be improved. Hereinafter, a configuration for optimizing movement path Nr set as described above and improving the efficiency of the setting process will be described.

### 6-2. Optimization of Movement Path

Path search section 52 may search for path pattern Hr based on accommodation information M4 and required number Ra of components 92 picked up in the pickup cycle scheduled to be executed in the path pattern search step (S34). That is, when number V1 (hereinafter referred to as number of components available for pickup Vc) of cavities 45 (accommodation cavities) that accommodate components 92 such that components 92 are available for pickup is larger than required number Ra in the pickup cycle scheduled to be executed (the pickup cycle including the unreached portion when executed in parallel), path search section 52 provides a condition in which required number Ra is the number of nodes of the traveling salesman problem.

With such a configuration, since movement path Nr for picking up required number Ra in the most recent pickup cycle is set, it is possible to improve the efficiency of the process of setting movement path Nr, and it is possible to improve the search speed associated with the decrease in the number of nodes, and to expect the optimization of movement path Nr. When number of components available for pickup Vc is larger than the sum of required numbers Ral and Ra2 of components 92 picked up in the pickup cycles scheduled to be executed in the successive PP cycles, path search section 52 may provide a condition in which required numbers Ral and Ra2 are the number of nodes, to the algorithm.

Here, in the initial improved solution, as illustrated in the middle part of FIG. 10, movement path Nr is set such that a route length between the nodes during the consecutive PP cycles (the length of the block indicated by an X mark connecting diagonal lines in FIG. 10) becomes as short as possible. However, since mounting head 133 actually moves to board 91 side, the route length between the nodes during the successive PP cycles does not contribute to the improvement of the overall efficiency even though the route length is shortened. Therefore, by providing the condition in consideration of required number Ra as described above, the route length during the successive PP cycles is allowed to be long, and movement path Nr in which the shortening of movement distance Lm of mounting head 133 in the pickup cycle is prioritized is set.

With such a configuration, as illustrated in the lower part of FIG. 10, in the conditionally improved solution, entire movement distance Lm is longer by difference Fd2 as compared with the initial improved solution, but movement distance Lm of mounting head 133 in the pickup cycle is shorter by difference FdV, which is effective. As described above, in the path pattern search step (S34), various conditions in accordance with the supply state of component 92 and the mounting process may be provided, so that more suitable movement path Nr can be set in accordance with the current situation.

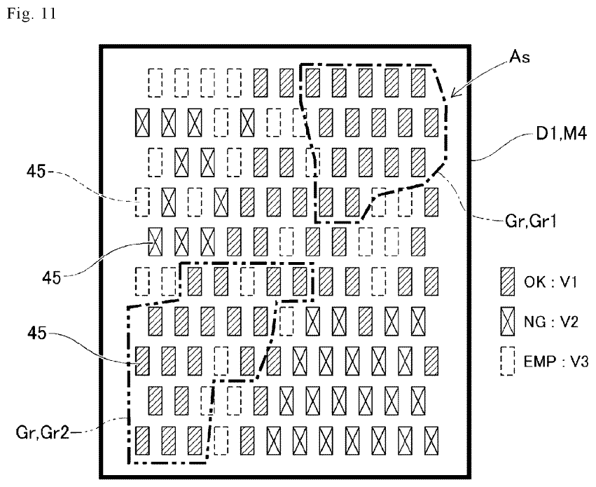

For example, path search section 52 may provide a condition on the assumption that the accommodation cavities may be biased in supply region As of bulk feeder 30. Specifically, first, as illustrated in FIG. 11, path search section 52 divides multiple cavities 45 into multiple groups Gr (Gr1 and Gr2) in accordance with the degree of bias of multiple cavities 45 (accommodation cavities) indicated by accommodation information M4 as accommodating components 92 such that components 92 are available for pickup. As a method of setting group Gr, for example, a method of searching for a closed region including an allowable number of NG cavities and empty cavities set in advance with reference to a portion in which a predetermined number of accommodation cavities are successive in at least one of the X direction and the Y direction is assumed.

Next, path search section 52 searches for path pattern Hr based on the number of cavities 45 (the number of accommodation cavities) included in each of multiple groups Gr (Gr1 and Gr2) and required number Ra (Ra1 and Ra2) of components 92 available for pickup in the pickup cycle scheduled to be executed. With such a configuration, since the path pattern is searched for in group Gr in which required number Ra can be ensured, it is possible to improve the efficiency of the process of setting movement path Nr, and it is possible to improve the search speed associated with the decrease in the number of nodes and to expect the optimization of movement path Nr.

For example, when number of components available for pickup Vc is larger than required number Ra (Ra1 and Ra2) in the pickup cycle of the successive PP cycles scheduled to be executed, path search section 52 may apply a method of searching for the path pattern not using group Gr in the process of setting movement path Nr related to the most recent PP cycle. Accordingly, the movement of mounting head 133 in the pickup cycle executed in parallel with the process of setting the movement path can be prioritized.

Then, in the process of setting movement path Nr related to the next PP cycle, switching may be performed to apply the method of searching for the path pattern using group Gr as a condition. As described above, by switching the algorithm and the condition as appropriate in consideration of the degree of progress of the mounting process, the supply state in supply region As, the execution schedule of the supply operation of component 92 by bulk feeder 30, and the like, it is possible to expect an improvement of the efficiency of the process of setting movement path Nr and the optimization of movement path Nr.

### 7. Modification of Embodiment

In the embodiment, a configuration is adopted in which mounting assistance device 50 is incorporated in control device 20 of component mounter 10.

Alternatively, mounting assistance device 50 may be incorporated in part or in whole into host computer 60 and other external devices. For example, mounting assistance device 50 may be a dedicated device incorporated in host computer 60 and installed in production line Ln.

### REFERENCE SIGNS LIST

10: component mounter, 12: component supply device, 13: component transfer device, 131: head drive device, 132: moving section, 133: mounting head, 134: suction nozzle, 14: part camera, 15: board camera, 20: control device, 21: storage section, 30: bulk feeder, 31: feeder main body, 40: track unit, 45: cavity, 50: mounting assistance device, 51: state recognition section, 52: path search section, 53: path setting section, 60: host computer, 91: board, 92: component, As: supply region, R: conveyance path, M1: control program, M2: component data, M3: cavity information, M4: accommodation information, D1: image data, Nr: movement path, Ni: preliminary path (initial solution), Hr: path pattern, Cf: first cavity, Ra, Ra1, Ra2: required number, Lm: movement distance, V1, Vc: number of components available for pickup, Gr, Gr1, Gr2: group

1. A mounting assistance device applied to a component mounter configured to execute a pickup cycle in which a mounting head is moved to sequentially pick up components accommodated in multiple cavities and a mounting cycle in which the multiple components are sequentially mounted on a board, the mounting assistance device comprising:
a path search section configured to search for path patterns that are candidates for a movement path of the mounting head in the pickup cycle based on accommodation information indicating, among the multiple cavities, positions of the multiple cavities that accommodate the components such that the components are available for pickup; and
a path setting section configured to set as the movement path the path pattern selected based on a movement distance of the mounting head calculated for each of multiple of the path patterns.

2. The mounting assistance device according to claim 1, wherein the path search section is configured to search for the path patterns based on the accommodation information and a required number of the components picked up in the pickup cycle scheduled to be executed.

3. The mounting assistance device according to claim 1,
wherein the component mounter is configured to execute a PP cycle including the pickup cycle and the mounting cycle multiple times, and
the path search section is configured to search for the path patterns based on the accommodation information and a required number of the components picked up in the pickup cycle scheduled to be executed in each of successive of the PP cycles.

4. The mounting assistance device according to claim 1, wherein the path search section is configured to divide the multiple cavities into multiple groups in accordance with a degree of bias of the multiple cavities indicated in the accommodation information as accommodating the components such that the components are available for pickup, and search for the path patterns based on the number of the cavities included in each of the multiple groups and a required number of the components picked up in the pickup cycle scheduled to be executed.

5. The mounting assistance device according to claim 1, wherein the path search section is configured to execute a determination step of determining a first cavity from which the component is first picked up by the mounting head in the path pattern among the multiple cavities that accommodate the components such that the components are available for pickup, and a search step of searching for the path patterns with reference to the first cavity.

6. The mounting assistance device according to claim 5, wherein the path search section is configured to set the first cavity based on a position of the mounting head when the pickup cycle is started.

7. The mounting assistance device according to claim 5, wherein the path search section is configured to execute the search step during a period in which the mounting head moves to the first cavity determined in the determination step.

8. The mounting assistance device according to claim 1, wherein, during a period in which the mounting head moves along the set movement path, the search for the path patterns by the path search section and the setting of the movement path by the path setting section are continued for a portion of the movement path not yet reached by the mounting head.

9. The mounting assistance device according to claim 1, wherein the path search section and the path setting section are configured to search for the path pattern and set the movement path, using an algorithm applied to solve a traveling salesman problem.

10. The mounting assistance device according to claim 9,
wherein the multiple cavities are arranged such that cavity rows each including the multiple cavities arranged along a first direction are arranged side by side in a second direction intersecting the first direction, and
the path search section is configured to provide a preliminary path formed by connecting end portions of paths along the cavity rows adjacent to each other with a path along the second direction, to the algorithm as an initial solution.

11. The mounting assistance device according to claim 1, further comprising:
a state recognition section configured to perform image processing on image data acquired by imaging a supply region for the component in a bulk feeder in which the multiple cavities are formed, recognize a supply state of the components in the supply region, and generate the accommodation information.

12. A mounting assistance method applied to a component mounter configured to execute a pickup cycle in which a mounting head is moved to sequentially pick up components accommodated in multiple cavities and a mounting cycle in which the multiple components are sequentially mounted on a board, the mounting assistance method comprising:
a path search step of searching for path patterns that are candidates for a movement path of the mounting head in the pickup cycle based on accommodation information indicating, among the multiple cavities, positions of the multiple cavities that accommodate the components such that the components are available for pickup; and
a path setting step of setting as the movement path the path pattern selected based on a movement distance of the mounting head calculated for each of multiple path patterns.
